(19) United States
(12) Patent Application Publication
(10) Pub. No.: US 2022/0030195 A1
(43) Pub. Date: Jan. 27, 2022

(54) CABLE TELEVISION APPARATUS WITH HIGH SATURATION CURRENT TRANSFORMER

(71) Applicant: CABLE VISION ELECTRONICS CO., LTD, New Taipei City (TW)

(72) Inventors: Chien-Chung LEE, New Taipei City (TW); Mao-Peng YU, New Taipei City (TW); I-Sheng TING, New Taipei City (TW)

(21) Appl. No.: 17/026,171

(22) Filed: Sep. 19, 2020

(51) Int. Cl. H04N 7/10; H01F 27/24; H01F 27/28; H03H 7/06; H01R 24/42

(52) U.S. Cl. CPC H04N 7/104; H01F 27/24; H01R 2103/00; H03H 7/06; H01R 24/42; H01F 27/28

(57) ABSTRACT

A cable television apparatus is applied to an input coaxial cable and an output coaxial cable to transmit a cable television signal and an alternating current power. The cable television apparatus includes a high saturation current transformer, an input terminal, an output terminal and a coupling side. The high saturation current transformer includes a ferrite core, a primary side circuit and a secondary side coil. The ferrite core is a high saturation current ferrite core, so that the primary side circuit transmits the cable television signal and the alternating current power, and couples the cable television signal to the secondary side coil.

### BACKGROUND OF THE INVENTION

### Field of the Invention

The present invention relates to a cable television apparatus, and especially relates to a cable television apparatus with a high saturation current transformer.

### Description of the Related Art

Currently, the cable television system is very popular. The cable television system transmits the television programs and the network signals to the client sides through the coaxial cables.

The cable television system needs to use the choke to transmit the alternating current power. Usually, the choke needs the winding, wherein the length of the winding is long, so that the choke easily generates the parasitic capacitances and the parasitic inductances; the notch (the undesired resonance) is generated easily at the high frequency, so that the high frequency characteristics are not good, especially at the frequency band above 1.5 GHz.

Moreover, using the choke in the cable television system increases the cost of the cable television system as well.

### SUMMARY OF THE INVENTION

In order to solve the above-mentioned problems, an object of the present invention is to provide a cable television apparatus with a high saturation current transformer.

In order to achieve the object of the present invention mentioned above, the cable television apparatus of the present invention is applied to an input coaxial cable and an output coaxial cable to transmit a cable television signal and an alternating current power. The cable television apparatus comprises the high saturation current transformer, an input terminal, an output terminal and a coupling side. The high saturation current transformer is electrically connected to the input coaxial cable and the output coaxial cable. The input terminal is electrically connected to the high saturation current transformer and the input coaxial cable. The output terminal is electrically connected to the high saturation current transformer and the output coaxial cable. The coupling side is electrically connected to the high saturation current transformer. Moreover, the high saturation current transformer comprises a ferrite core, a primary side circuit and a secondary side coil. One side of the primary side circuit is electrically connected to the input coaxial cable and the input terminal. The other side of the primary side circuit is electrically connected to the output coaxial cable and the output terminal. The secondary side coil winds the ferrite core. One side of the secondary side coil is electrically connected to ground. The other side of the secondary side coil is electrically connected to the coupling side. Moreover, the ferrite core is a high saturation current ferrite core, so that the primary side circuit transmits the cable television signal and the alternating current power, and couples the cable television signal to the secondary side coil.

Moreover, in an embodiment of the cable television apparatus of the present invention mentioned above, a bearable current of the primary side circuit can be, for example but not limited to, greater than or equal to 10 amperes. When the bearable current of the primary side circuit is greater than or equal to 10 amperes, the ferrite core still does not saturate (namely, the ferrite core is in a non-saturation status).

Moreover, in an embodiment of the cable television apparatus of the present invention mentioned above, the ferrite core defines a gap to achieve the high saturation current ferrite core.

Moreover, in an embodiment of the cable television apparatus of the present invention mentioned above, the ferrite core defines a central hole. The primary side circuit is a conductive straight wire through the central hole.

Moreover, in an embodiment of the cable television apparatus of the present invention mentioned above, the cable television apparatus of the present invention further comprises a coupling side transformer electrically connected to the secondary side coil and the coupling side. The coupling side transformer is electrically connected to the input terminal or the output terminal.

Moreover, in an embodiment of the cable television apparatus of the present invention mentioned above, the cable television apparatus of the present invention further comprises a first resistor. One side of the first resistor is electrically connected to ground. The other side of the first resistor is electrically connected to the secondary side coil and the coupling side transformer.

Moreover, in an embodiment of the cable television apparatus of the present invention mentioned above, the cable television apparatus of the present invention further comprises a second resistor, a third resistor and a capacitor. The second resistor is electrically connected to the first resistor, the secondary side coil and the coupling side transformer. The third resistor is electrically connected to the input terminal or the output terminal. The capacitor is electrically connected to the third resistor and the coupling side transformer.

Moreover, in an embodiment of the cable television apparatus of the present invention mentioned above, the cable television apparatus of the present invention further comprises a splitting circuit electrically connected to the coupling side.

Moreover, in an embodiment of the cable television apparatus of the present invention mentioned above, the cable television apparatus of the present invention further comprises a capacitor electrically connected to the output terminal and the coupling side transformer.

Moreover, in an embodiment of the cable television apparatus of the present invention mentioned above, a coil turn number of the secondary side coil is, for example but not limited to, 5 or 6.

Moreover, in an embodiment of the cable television apparatus of the present invention mentioned above, a diameter of the conductive straight wire is, for example but not limited to, at least 0.8 millimeter.

Moreover, in an embodiment of the cable television apparatus of the present invention mentioned above, the ferrite core can be, for example but not limited to, made of manganese zinc.

Moreover, in an embodiment of the cable television apparatus of the present invention mentioned above, the cable television apparatus of the present invention further comprises a printed circuit board, wherein the primary side circuit is arranged on one side of the printed circuit board.

Moreover, in an embodiment of the cable television apparatus of the present invention mentioned above, the printed circuit board defines an accommodating hole. The ferrite core is through the accommodating hole and is arranged in the accommodating hole.

Moreover, in an embodiment of the cable television apparatus of the present invention mentioned above, the cable television apparatus of the present invention further comprises a metal lower cover arranged on the other side of the printed circuit board. The metal lower cover covers the ferrite core.

Moreover, in an embodiment of the cable television apparatus of the present invention mentioned above, the cable television apparatus of the present invention further comprises a metal upper cover arranged on one side of the printed circuit board. The metal upper cover covers the ferrite core.

Moreover, in an embodiment of the cable television apparatus of the present invention mentioned above, the cable television apparatus of the present invention further comprises a separator surrounding a part of the primary side circuit to avoid the primary side circuit having a short circuit with the secondary side coil.

Moreover, in an embodiment of the cable television apparatus of the present invention mentioned above, the conductive straight wire is a part of the input terminal or a part of the output terminal.

Moreover, in an embodiment of the cable television apparatus of the present invention mentioned above, the cable television apparatus of the present invention further comprises a metal cap surrounding the high saturation current transformer.

Moreover, in an embodiment of the cable television apparatus of the present invention mentioned above, the metal cap is a part of the input terminal or a part of the output terminal.

Because the present invention does not use the choke to transmit the alternating current power, the present invention can greatly improve the high frequency characteristics of the cable television signal and reduce the cost of the cable television system.

Please refer to the detailed descriptions and figures of the present invention mentioned below for further understanding the technology, method and effect of the present invention achieving the predetermined purposes. It believes that the purposes, characteristic and features of the present invention can be understood deeply and specifically. However, the figures are only for references and descriptions, but the present invention is not limited by the figures.

### BRIEF DESCRIPTION OF DRAWINGS

FIG. 1 shows a circuit block diagram of the first embodiment of the cable television apparatus of the present invention.

FIG. 2 shows a circuit block diagram of the second embodiment of the cable television apparatus of the present invention.

FIG. 3 shows a circuit block diagram of the third embodiment of the cable television apparatus of the present invention.

FIG. 4 shows a circuit block diagram of the fourth embodiment of the cable television apparatus of the present invention.

FIG. 5 shows a schematic diagram of an embodiment of the high saturation current transformer of the present invention.

FIG. 6 shows a side sectional view of an embodiment of the cable television apparatus of the present invention.

FIG. 7 shows a side sectional view of another embodiment of the high saturation current transformer of the present invention.

FIG. 8 shows a side sectional view of still another embodiment of the high saturation current transformer of the present invention.

### DETAILED DESCRIPTION OF THE INVENTION

In the present disclosure, numerous specific details are provided, to provide a thorough understanding of embodiments of the invention. Persons of ordinary skill in the art will recognize, however, that the present invention can be practiced without one or more of the specific details. In other instances, well-known details are not shown or described to avoid obscuring aspects of the present invention. Now please refer to the figures for the explanation of the technical content and the detailed description of the present invention:

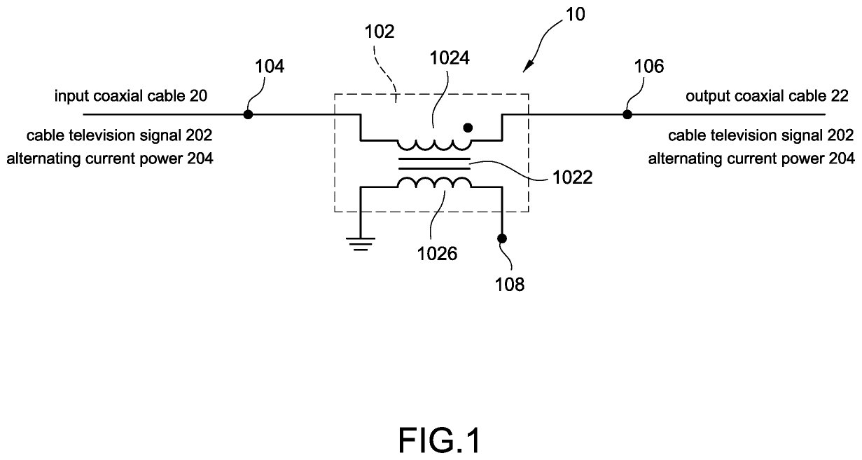

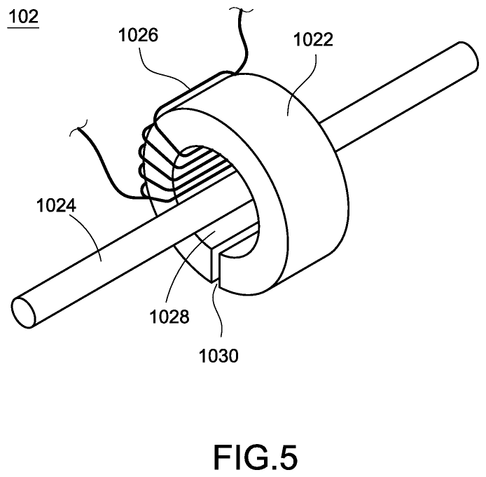

FIG. 1 shows a circuit block diagram of the first embodiment of the cable television apparatus of the present invention. The cable television apparatus 10 of the present invention is applied to an input coaxial cable 20 and an output coaxial cable 22 to transmit a cable television signal 202 and an alternating current power 204. The cable television apparatus 10 comprises a high saturation current transformer 102, an input terminal 104, an output terminal 106 and a coupling side 108. The high saturation current transformer 102 comprises a ferrite core 1022, a primary side circuit 1024 and a secondary side coil 1026. The components mentioned above are electrically connected to each other, and the secondary side coil 1026 winds the ferrite core 1022 (as shown in FIG. 5).

The ferrite core 1022 is a high saturation current ferrite core, so that the primary side circuit 1024 transmits the cable television signal 202 and the alternating current power 204, and couples the cable television signal 202 to the secondary side coil 1026. A bearable current of the primary side circuit 1024 can be, for example but not limited to, greater than or equal to 10 amperes. When the bearable current of the primary side circuit 1024 is greater than or equal to 10 amperes, the ferrite core 1022 still does not saturate (namely, the ferrite core 1022 is in a non-saturation status).

FIG. 5 shows a schematic diagram of an embodiment of the high saturation current transformer of the present invention. The descriptions of the elements shown in FIG. 5 which are the same as the elements shown in FIG. 1 are not repeated here for brevity. The ferrite core 1022 defines a gap 1030 to achieve the high saturation current ferrite core, but the present invention is not limited to it; namely, the high saturation current ferrite core can be achieved by any other methods. The ferrite core 1022 defines a central hole 1028. The primary side circuit 1024 is a conductive straight wire through the central hole 1028, but the present invention is not limited to it; namely, the primary side circuit 1024 can be a primary side coil winding the ferrite core 1022 as well. A diameter of the conductive straight wire is, for example but not limited to, at least 0.8 millimeter. A coil turn number of the secondary side coil 1026 is, for example but not limited to, 5 or 6. The ferrite core 1022 can be, for example but not limited to, made of manganese zinc.

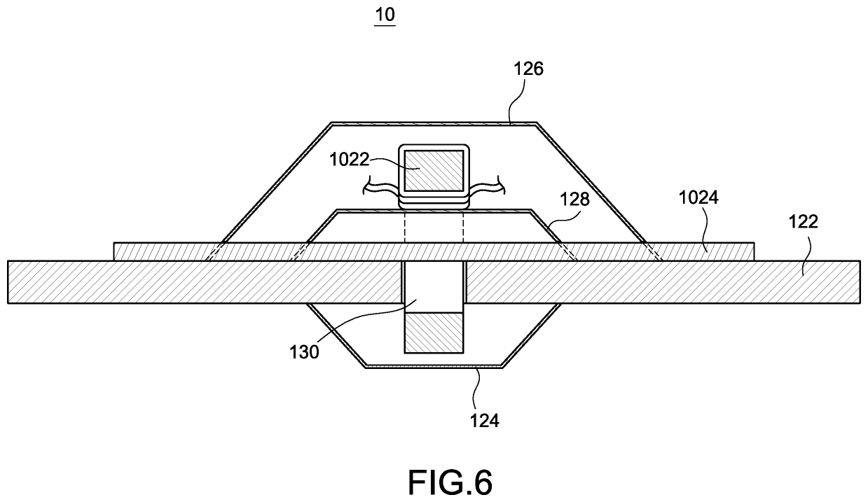

FIG. 6 shows a side sectional view of an embodiment of the cable television apparatus of the present invention. The descriptions of the elements shown in FIG. 6 which are the same as the elements shown in FIG. 1 and FIG. 5 are not repeated here for brevity. The cable television apparatus 10 further comprises a printed circuit board 122, a metal lower cover 124, a metal upper cover 126 and a separator 128. The printed circuit board 122 defines an accommodating hole 130.

The ferrite core 1022 is through the accommodating hole 130 and is arranged in the accommodating hole 130. The primary side circuit 1024 is arranged on one side of the printed circuit board 122. The metal lower cover 124 is arranged on the other side of the printed circuit board 122. The metal lower cover 124 covers the ferrite core 1022. The metal upper cover 126 is arranged on one side of the printed circuit board 122. The metal upper cover 126 covers the ferrite core 1022. The separator 128 surrounds a part of the primary side circuit 1024 to avoid the primary side circuit 1024 having a short circuit with the secondary side coil 1026. Moreover, the separator 128 can be, for example but not limited to, a heat shrink tubing.

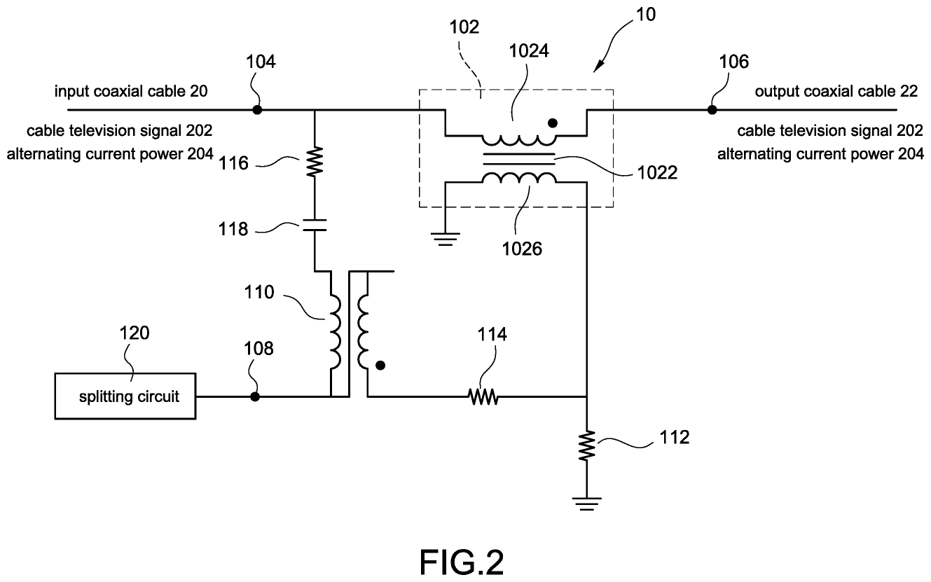

FIG. 2 shows a circuit block diagram of the second embodiment of the cable television apparatus of the present invention. The descriptions of the elements shown in FIG. 2 which are the same as the elements shown in the figures mentioned above are not repeated here for brevity. The cable television apparatus 10 further comprises a coupling side transformer 110, a first resistor 112, a second resistor 114, a third resistor 116, a capacitor 118 and a splitting circuit 120. The components mentioned above are electrically connected to each other.

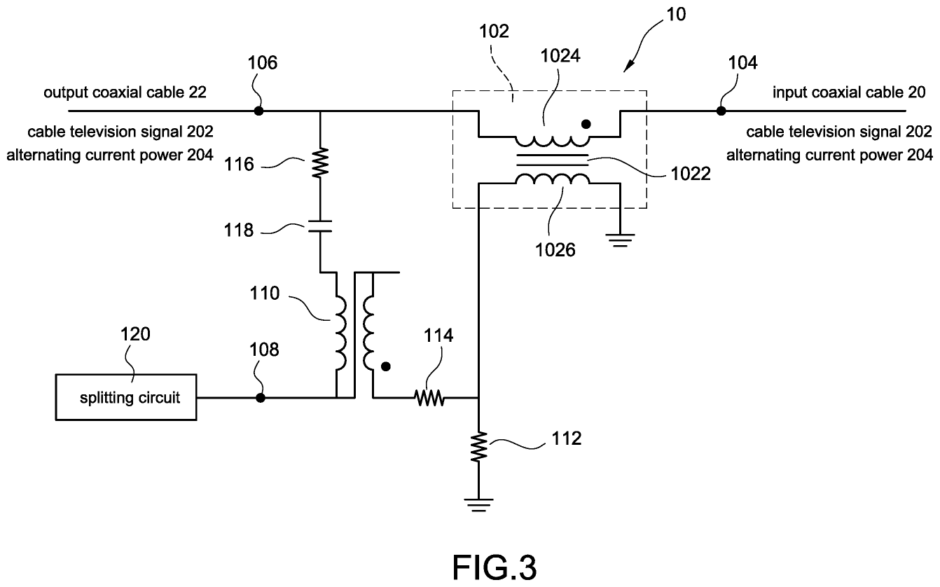

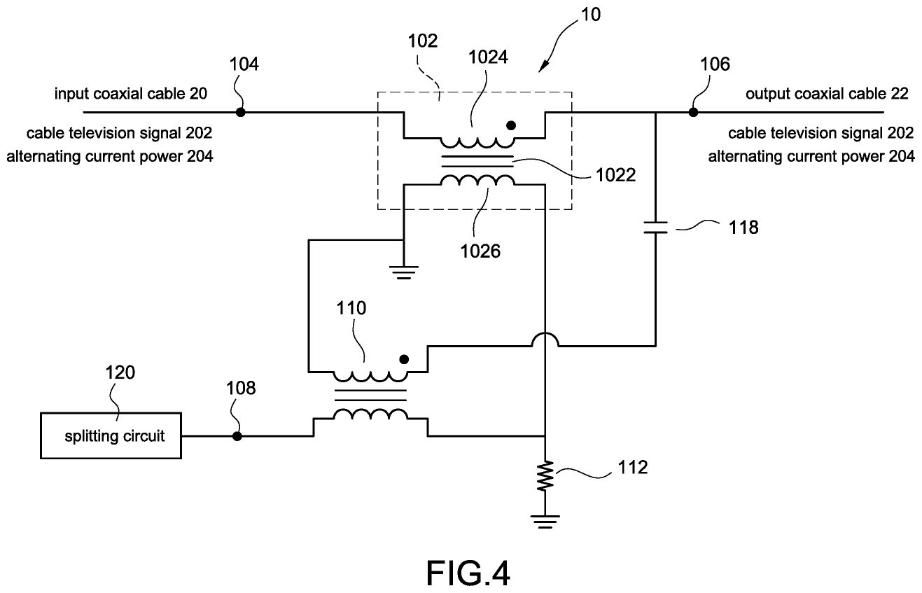

FIG. 3 shows a circuit block diagram of the third embodiment of the cable television apparatus of the present invention. The descriptions of the elements shown in FIG. 3 which are the same as the elements shown in the figures mentioned above are not repeated here for brevity. FIG. 4 shows a circuit block diagram of the fourth embodiment of the cable television apparatus of the present invention. The descriptions of the elements shown in FIG. 4 which are the same as the elements shown in the figures mentioned above are not repeated here for brevity.

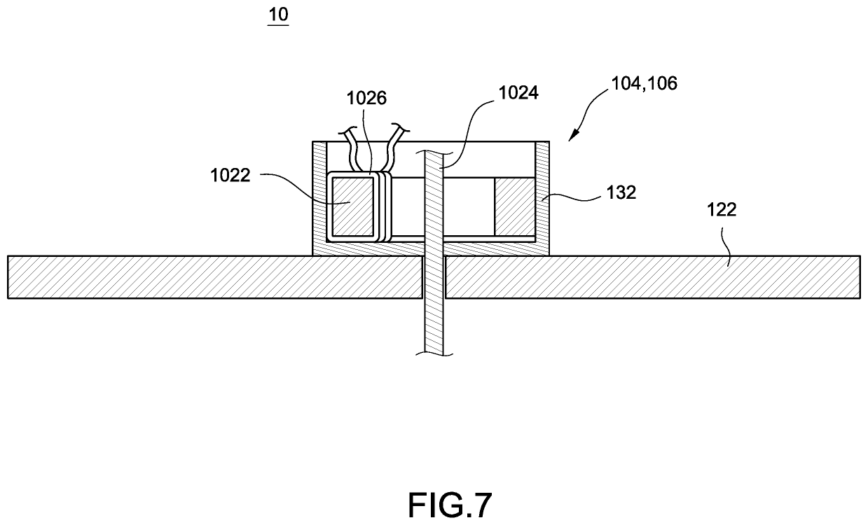

FIG. 7 shows a side sectional view of another embodiment of the high saturation current transformer of the present invention. The descriptions of the elements shown in FIG. 7 which are the same as the elements shown in the figures mentioned above are not repeated here for brevity. As shown in FIG. 7, the conductive straight wire (namely, the primary side circuit 1024) is a part of the input terminal 104 (namely, a connector signal transmission pin) or a part of the output terminal 106 (namely, a connector signal transmission pin). The cable television apparatus 10 further comprises a metal cap 132 surrounding the high saturation current transformer 102. The metal cap 132 is a part of the input terminal 104 (namely, a connector ground metal housing) or a part of the output terminal 106 (namely, a connector ground metal housing). Moreover, the input terminal 104 and the output terminal 106 are connectors and are arranged on one side of the printed circuit board 122. The high saturation current transformer 102 is arranged in the input terminal 104 or the output terminal 106.

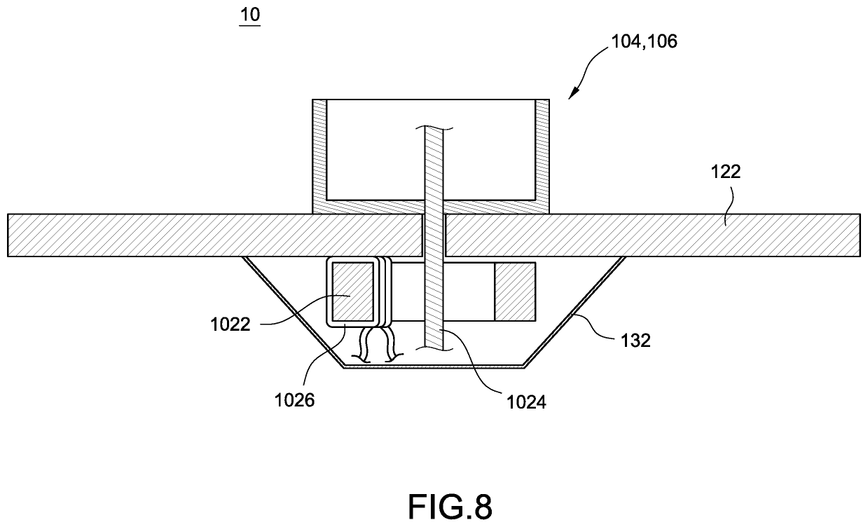

FIG. 8 shows a side sectional view of still another embodiment of the high saturation current transformer of the present invention. The descriptions of the elements shown in FIG. 8 which are the same as the elements shown in the figures mentioned above are not repeated here for brevity. As shown in FIG. 8, the conductive straight wire (namely, the primary side circuit 1024) is a part of the input terminal 104 (namely, a connector signal transmission pin) or a part of the output terminal 106 (namely, a connector signal transmission pin). The cable television apparatus 10 further comprises a metal cap 132 surrounding the high saturation current transformer 102. Moreover, the input terminal 104 and the output terminal 106 are connectors and are arranged on one side of the printed circuit board 122. The high saturation current transformer 102 and the metal cap 132 are arranged on the other side of the printed circuit board 122.

Moreover, in an embodiment of the present invention, the input terminal 104 and the output terminal 106 mentioned above are arranged on one side of the printed circuit board 122 to be respectively connected to a case side input terminal (not shown in the figures) and a case side output terminal (not shown in the figures) of a case (not shown in the figures). In another embodiment of the present invention, the input terminal 104 and the output terminal 106 mentioned above are arranged on the case to be respectively connected and locked to the input coaxial cable 20 and the output coaxial cable 22.

Because the present invention does not use the choke to transmit the alternating current power, the present invention can greatly improve the high frequency characteristics of the cable television signal and reduce the cost of the cable television system.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A cable television apparatus applied to an input coaxial cable and an output coaxial cable to transmit a cable television signal and an alternating current power, the cable television apparatus comprising:
a high saturation current transformer electrically connected to the input coaxial cable and the output coaxial cable;
an input terminal electrically connected to the high saturation current transformer and the input coaxial cable;
an output terminal electrically connected to the high saturation current transformer and the output coaxial cable; and
a coupling side electrically connected to the high saturation current transformer,
wherein the high saturation current transformer comprises:
a ferrite core;
a primary side circuit, one side of the primary side circuit electrically connected to the input coaxial cable and the input terminal, the other side of the primary side circuit electrically connected to the output coaxial cable and the output terminal; and
a secondary side coil winding the ferrite core, one side of the secondary side coil electrically connected to ground, the other side of the secondary side coil electrically connected to the coupling side,
wherein the ferrite core is a high saturation current ferrite core, so that the primary side circuit transmits the cable television signal and the alternating current power, and couples the cable television signal to the secondary side coil.

2. The cable television apparatus of claim 1, wherein a bearable current of the primary side circuit is greater than or equal to 10 amperes; when the bearable current of the primary side circuit is greater than or equal to 10 amperes, the ferrite core still does not saturate.

3. The cable television apparatus of claim 2, wherein the ferrite core defines a gap to achieve the high saturation current ferrite core.

4. The cable television apparatus of claim 3, wherein the ferrite core defines a central hole; the primary side circuit is a conductive straight wire through the central hole.

5. The cable television apparatus of claim 4, further comprising:
a coupling side transformer electrically connected to the secondary side coil and the coupling side, the coupling side transformer electrically connected to the input terminal or the output terminal.

6. The cable television apparatus of claim 5, further comprising:
a first resistor, one side of the first resistor electrically connected to ground, the other side of the first resistor electrically connected to the secondary side coil and the coupling side transformer.

7. The cable television apparatus of claim 6, further comprising:
a second resistor electrically connected to the first resistor, the secondary side coil and the coupling side transformer;
a third resistor electrically connected to the input terminal or the output terminal; and
a capacitor electrically connected to the third resistor and the coupling side transformer.

8. The cable television apparatus of claim 7, further comprising:
a splitting circuit electrically connected to the coupling side.

9. The cable television apparatus of claim 6, further comprising:
a capacitor electrically connected to the output terminal and the coupling side transformer.

10. The cable television apparatus of claim 4, wherein a coil turn number of the secondary side coil is 5 or 6.

11. The cable television apparatus of claim 4, wherein a diameter of the conductive straight wire is at least 0.8 millimeter.

12. The cable television apparatus of claim 3, wherein the ferrite core is made of manganese zinc.

13. The cable television apparatus of claim 4, further comprising:
a printed circuit board,
wherein the primary side circuit is arranged on one side of the printed circuit board.

14. The cable television apparatus of claim 13, wherein the printed circuit board defines an accommodating hole; the ferrite core is through the accommodating hole and is arranged in the accommodating hole.

15. The cable television apparatus of claim 14, further comprising:
a metal lower cover arranged on the other side of the printed circuit board; the metal lower cover covers the ferrite core.

16. The cable television apparatus of claim 15, further comprising:
a metal upper cover arranged on one side of the printed circuit board; the metal upper cover covers the ferrite core.

17. The cable television apparatus of claim 4, further comprising:
a separator surrounding a part of the primary side circuit to avoid the primary side circuit having a short circuit with the secondary side coil.

18. The cable television apparatus of claim 4, wherein the conductive straight wire is a part of the input terminal or a part of the output terminal.

19. The cable television apparatus of claim 18, further comprising:
a metal cap surrounding the high saturation current transformer.

20. The cable television apparatus of claim 19, wherein the metal cap is a part of the input terminal or a part of the output terminal.
